(19) United States
(12) Patent Application Publication
(10) Pub. No.: US 2025/0176277 A1
(43) Pub. Date: May 29, 2025

(54) ELECTROSTATIC DISCHARGE PROTECTION DEVICE

(71) Applicant: Sofics BV, Gistel (BE)

(72) Inventors: Bart Paul SORGELOOS, Gistel (BE); Olivier MARICHAL, Gistel (BE); Johan VAN DER BORGHT, Gistel (BE)

(73) Assignee: Sofics BV, Gistel (BE)

(21) Appl. No.: 18/840,352

(22) PCT Filed: Feb. 20, 2023
(86) PCT No.: PCT/EP2023/054220

§ 371 Date: Aug. 21, 2024

(30) Foreign Application Priority Data
Feb. 21, 2022 (BE) 2022/5113

(51) Int. Cl. H10D 89/60

(52) U.S. Cl. CPC H10D 89/713

(57) ABSTRACT

An electrostatic discharge, ESD, protection device coupled between a first node and a second node, said ESD protection device comprising: a first branch between the first node and the second node, said first branch comprising a switching device and a triggering device coupled to the switching device and configured to switch on the switching device during an ESD event; a second branch between the first node and the second node, said second branch comprising a stack of transistors, wherein an interconnection node interconnects a first transistor and second transistor of said stack, wherein the second branch is electrically connected such that, in operation, a DC voltage drop between said interconnection node and the first node is lower than a DC voltage applied between the first and the second node.

### CROSS-REFERENCE TO RELATED APPLICATIONS

This application is the U.S. National Stage, under 35 U.S.C. § 371, of International Application No. PCT/EP2023/054220, filed Feb. 20, 2023, which claims priority to Belgium Patent Application No. 2022/5113, filed Feb. 21, 2022, the contents of which are incorporated herein by reference.

### FIELD OF THE INVENTION

The invention generally relates to electrostatic discharge (ESD) protection devices, and in particular ESD devices allowing the use of more advanced transistor technologies and/or with additional trigger possibilities.

### BACKGROUND OF THE INVENTION

During ESD, large currents can flow through an IC which can potentially cause damage. Damage can occur within the devices that conduct the current, as well as in devices that see a significant voltage drop due to the large current flow. To avoid damage due to an ESD event, an ESD protection device is added to the IC. These ESD protection devices may shunt the large ESD current without causing high voltage over sensitive nodes of the IC.

FIGS. 1A-1C depict conventional ESD protection devices. The ESD protection device comprises a switching device 110 consisting of an SCR 110 with possible holding diodes 130 coupled between the node to be protected, here called the first node 1, and the anode A of the SCR 110. Since an SCR 110 has a high trigger voltage, typically one or more additional triggering devices are included. In FIGS. 1A-1C, the ESD protection device comprises a DC-level triggering device 120 comprising one or more diodes connected in series between a trigger tap G2 of the SCR 110 and the cathode C of the SCR 110, which corresponds with the second node 2. In FIG. 1A, a transient triggering device 500 is provided between the trigger tap G2 and the cathode C. The transient triggering device 500 comprises a MOS transistor 510 and a transient detector comprising a resistor 530 connected between the gate G of the transistor 510 and the cathode C and a capacitor 520 connected between the gate G of the transistor 510 and the first node 1. Such transient triggering device 500 may be faster than the DC-level triggering device 120. FIG. 1B shows a similar transient triggering device 500, but here the drain D of the MOS transistor 510 is connected to the first node 1 in order to limit the overshoot. In FIG. 1C a combination of FIGS. 1A and 1B is used with the drain D of a first MOS transistor 510 being connected to the trigger tap G2 of the SCR 110 and the drain D a second MOS transistor 510′ being connected to the first node 1. Further, in FIGS. 1A-1C, a bulk B coupling of the transistor(s) 510, 510′ may be present.

### SUMMARY OF THE INVENTION

The object of embodiments of the invention is to provide an electrostatic discharge, ESD, protection device which allows using new more advanced transistor technologies, like fin field-effect transistors, FinFETs and/or improving trigger possibilities and/or allowing obtaining an integrated circuit (including the ESD protection device) having a reduced surface area.

According to a first aspect there is provided an electrostatic discharge, ESD, protection device coupled between a first node and a second node. The ESD protection device comprises a first branch having a clamping function and a second branch having a transient triggering function. The first branch is electrically coupled between the first node and the second node. The first branch comprises a switching device and a triggering device coupled to the switching device and configured to switch on the switching device during an ESD event. The second branch is electrically coupled between the first node and the second node. The second branch comprises a stack of n transistors, n being at least two. An interconnection node interconnects a first transistor and second transistor of said stack of transistors. The second branch is electrically connected such that, in operation, a DC voltage drop between the interconnection node and the first node is lower than a DC voltage applied between the first node and the second node, preferably at most (100/n+20)% of the DC voltage applied between the first node and the second node, more preferably at most (100/n+10)% of the DC voltage applied between the first node and the second node.

By providing a second branch with a stack of transistors connected in series and by connecting the second branch such that a critical voltage over a transistor of the stack is limited, transistors which a reduced voltage rating, e.g. more advanced smaller transistors, may be used.

Preferably, the stack of transistors is electrically connected such that, in operation, a maximum DC voltage drop over each transistor of said stack is limited to a value which is lower than a DC voltage applied between the first and the second node, preferably at most (100/n+20)% of the DC voltage applied between the first and the second node, more preferably at most (100/n+10)% of the DC voltage applied between the first node and the second node. For example, when the stack comprises MOS transistors connected in series, e.g. a stack where a source of an upper NMOS transistor is connected to a drain of a lower NMOS transistor or a stack where a drain of an upper PMOS transistor is connected to a source of the lower PMOS transistor, it is preferred that:
a maximum DC voltage drop between the drain D and the source S of each MOS transistor is limited to a value which is lower than a DC voltage applied between the first node and the second node, preferably at most (100/n+20)% of the DC voltage applied between the first and the second node, more preferably at most (100/n+10)% of the DC voltage applied between the first node and the second node;
a maximum DC voltage drop between the gate G and the source S of each MOS transistor is limited to a value which is lower than a DC voltage applied between the first node and the second node, preferably at most (100/n+20)% of the DC voltage applied between the first and the second node, more preferably at most (100/n+10)% of the DC voltage applied between the first node and the second node; and
a maximum DC voltage drop between the drain D and the gate G of each MOS transistor is limited to a value which is lower than a DC voltage applied between the first node and the second node, preferably at most (100/n+20)% of the DC voltage applied between the first and the second node, more preferably at most (100/n+10)% of the DC voltage applied between the first node and the second node.

More in particular, the number of transistors of the stack may be chosen so that no current is drawn by the stack when a normal operation voltage is applied between the first and the second node. Limiting these voltage drops can be achieved in various ways by suitably connecting the second branch. For example, the interconnection node may be directly connected to a suitable node of the first branch, or the gate of one or more of the transistors may be connected to a suitable node of the first branch.

According to a second aspect there is provided an electrostatic discharge, ESD, protection device coupled between a first node and a second node. The ESD protection device comprises a first branch having a clamping function and a second branch having a transient triggering function. The first branch is electrically coupled between the first node and the second node. The first branch comprises a switching device and a triggering device coupled to the switching device and configured to switch on the switching device during an ESD event. The second branch is electrically coupled between the first node and the second node. The second branch comprises a stack of transistors. An interconnection node interconnects a first transistor and second transistor of said stack. The second branch is connected to the first branch in a branch connection node which is different from the first and the second node.

By suitable connecting the second branch to the first branch, an improved triggering of the switching device can be achieved.

Preferably, the branch connection node is electrically connected to the interconnection node or to a gate or base of a transistor of said stack of transistors of the second branch. When the transistor is a MOS transistor the branch connection node may be connected to the gate thereof and when the transistor is a bipolar transistor the branch connection node may be connected to the base thereof.

Preferably, the branch connection node is electrically connected to a triggering node of the triggering device of the first branch.

The advantage of connecting on the one hand the branch connection node to the interconnection node and on the other hand to a triggering node, i.e. of connecting a triggering node to the interconnection node, is that, when an ESD event happens, the current flowing through the first branch will be drawn also to the interconnection node, accelerating the clamping action.

The advantage of connecting on the one hand the branch connection node to the gate of one of the transistors and on the other hand to a triggering node, i.e. of connecting a triggering node to the gate of one of the transistors and in particular to the gate of an upper transistor of the stack if the transistors are NMOS transistors, is that all transistors of the second branch may be turned on, which also helps in triggering the clamping action.

Preferably, the first branch comprises a holding device connected in series with the switching device between the first and the second node. In such an embodiment, the branch connection node may also be electrically connected to an internal node of the holding device.

The advantage of connecting on the one hand the branch connection node to the interconnection node or to a gate/base, and on the other hand to a holding node, i.e. of connecting a holding node to the interconnecting node, is that the interconnection node or the gate/base can be put at a desired voltage by using a suitable holding node. Especially when the stack comprises more than two transistors, and thus more than one interconnection node, such embodiments may be advantageous. In an embodiment with a stack of three or more transistors in the second branch, for example, a first upper interconnection node may be connected to a holding node and a second lower interconnection node may be connected to a triggering node. In another example a gate of an upper transistor of the stack may be connected to a holding node and a lower interconnection node may be connected to a triggering node.

Preferably, the stack of transistors consists of a stack of at least two metal oxide semiconductor, MOS, transistors. NMOS transistors and/or PMOS transistors may be used. Alternatively bipolar transistors may be used, but generally MOS transistors are preferred. Embodiments of the invention are particularly advantageous when advanced MOS transistors having a reduced voltage rating, such as fin field-effect transistors, Fin-FETs, are used in the second branch.

Preferably, each of the transistors has a voltage rating below 2.0V, for example a voltage rating of 1.8V or 1.5V or 1.2V.

A voltage rating for a transistor is defined as a maximum voltage that may be applied to a transistor and for which the characteristics of the transistors (Vth, IDsat, . . . ) are guaranteed to changes only within a maximum range for a predefined time (10 years mostly), and this for 99.9% of the transistors. This voltage rating is typically defined by the foundry/fab and provided to the designers. The value is based on measurements and simulations for Hot Carrier Injection (HCI), Bias Temperature instability (BTI), Time dependent dielectrical Breakdown (TDDB), Electro migration (EM), etc.

Preferably, the switching device comprises a silicon controlled rectifier, SCR. The triggering device may then be connected between a trigger tap of the SCR and one of the first node and the second node. Typically, the SCR comprises a first NPN bipolar transistor, a second PNP bipolar transistor and a resistive component. The triggering device may be connected between a trigger tap of the second PNP bipolar transistor of the SCR and the first or second node.

Preferably, the ESD protection device further comprises a transient detector, preferably coupled between the first node and the second node or between the first node and the interconnection node, said transient detector comprising a resistive element and a capacitive element. A gate or base of a transistor of said stack is connected to an intermediate node of the transient detector, said intermediate node interconnecting the resistive element and the capacitive element.

In an exemplary embodiment, the ESD protection device further comprises a resistive element coupled between the interconnection node and a gate or base of one of said first and second transistor. For example, such a resistive element may be added for transistors of the stack for which the gate or base is not connected to a transient detector. Alternatively, when the transistors are MOS transistors, the gate of a transistor of the stack may be directly connected to the source.

In an exemplary embodiment, the triggering device comprises at least one diode, preferably at least two diodes. For example, the triggering device may comprise at least two diodes and a diode interconnecting node interconnecting two diodes thereof may be connected to the branch connection node.

In another exemplary embodiment, the triggering device comprises a resistive divider coupled between the first node and the second node, and an intermediate node of the resistive divider, i.e. a node interconnecting two resistive elements of the resistive divider, is coupled to a trigger tap of the switching device.

In an exemplary embodiment, the holding device comprises at least one diode, preferably at least two diodes. For example, the holding device may comprise at least two diodes connected in series, and a diode interconnecting node interconnecting two diodes thereof may be connected to the branch connection node.

In some exemplary embodiments, the stack may comprise at least three transistors or at least four transistors. More generally, the number of transistors may be chosen e.g. in function of the voltage rating of the transistors and the desired operating voltages of the ESD protection device. For example, when the ESD protection device needs to have a clamping voltage of 3.3V, the stack may consist of two transistors (n=2) with a voltage rating of 1.8V or three transistors (n=3) with a voltage rating of 1.2V. In another example, when the ESD protection device needs to have a clamping voltage of 5V, the stack may consist of three transistors (n=3) with a voltage rating of 1.8V. Also, transistors having a different voltage rating may be combined in the same stack.

On another exemplary embodiment, the ESD protection device comprises a resistive divider coupled between the first node and the second node, wherein an intermediate node of the resistive divider, i.e. a node interconnecting two resistive elements of the resistive divider, is coupled to the interconnection node of the second branch. When the stack comprises more than two transistors, and thus more than one interconnection node, the resistive divider may also comprise more than two resistive elements, so that an upper internal node of the resistive divider may be connected to an upper interconnection node of the second branch and a lower internal node of the resistive divider may be connected to a lower interconnection node of the second branch.

### BRIEF DESCRIPTION OF THE DRAWINGS

The accompanying drawings are used to illustrate presently preferred non-limiting exemplary embodiments of devices of the present invention. The above and other advantages of the features and objects of the invention will become more apparent, and the invention will be better understood from the following detailed description when read in conjunction with the accompanying drawings, in which:

FIGS. 1A-C are circuit schematics of three conventional ESD protection devices;

FIG. 2 is a circuit schematic of an embodiment of an ESD protection device with a stack of two NMOS transistors;

FIGS. 3A, 3B, 4, 5, 6 are circuit schematics of further exemplary embodiments of an ESD protection device with a stack of two NMOS transistors;

FIGS. 7A-7G are circuit schematics of exemplary embodiments of an ESD protection device with a stack of three NMOS transistors;

FIG. 8 is a circuit schematic of an embodiment of an ESD protection device with a stack of two PMOS transistors;

FIGS. 9A and 9B are circuit schematics of further exemplary embodiments of an ESD protection device with an electrical connection between the first branch and the second branch; and

FIG. 10 is a circuit schematic of an embodiment of an ESD protection device with an alternative structure for limiting a voltage over each of the transistors of the second branch.

### DESCRIPTION OF EMBODIMENTS

In the following descriptions, common numerical designations may be used for similar, corresponding parts across multiple figures.

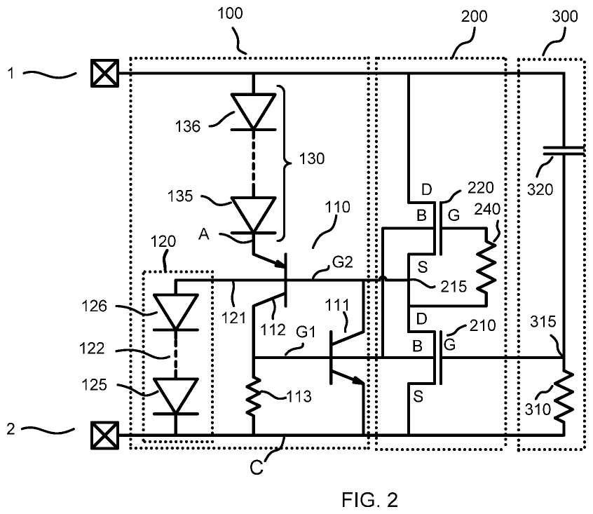

FIG. 2 depicts a first embodiment of an ESD protection device. The ESD protection device is coupled between a node to be protected, here the first node 1 and a second node 2. The ESD protection device comprises a first branch 100 electrically interconnecting the first node 1 and the second node 2 and a second branch 200 electrically interconnecting the first node 1 and the second node 2. The term “branch” is to be understood as a plurality of interconnected electrical components extending between the first node 1 and the second node 2. A branch may comprise electrical components connected in series and/or in parallel.

The first branch 100 comprises a switching device 110 and a triggering device 120 coupled to the switching device 110 and configured to switch on the switching device 110 during an ESD event. Preferably, the first branch 100 comprises a holding device 130 connected in series with the switching device 110 between the first and the second node 2.

The second branch 200 comprises a stack of at least two transistors, here a first transistor 210 and a second transistor 220. An interconnection node 215 interconnects the first transistor 210 and the second transistor 220. Preferably, the at least two transistors are at least two metal oxide semiconductor (MOS) transistors having a drain D, a source S, a gate G and optionally a bulk B connection. The MOS transistors may be NMOS and/or PMOS transistors. In the example of FIG. 2, two NMOS transistors have been included. The interconnection node 215 corresponds here with the drain D of the first transistor 210 and the source S of the second transistor 220. The source S of the first transistor 210 is connected to the second node 2 and the drain D of the second transistor 220 is connected to the first node 1. The interconnection node 215 is electrically connected such that, in operation, a voltage drop between the interconnection node 215 and the second node 2 is always lower than a voltage applied between the first node 1 and the second node 2, preferably at most 70% of the voltage applied between the first node 1 and the second node 2, more preferably at most 60% of the voltage applied between the first node 1 and the second node 2. Preferably, the stack of the at least two transistors is electrically connected such that, in normal operation,
a maximum voltage drop between the drain D and the source S of each transistor 210, 220 is limited to a value which is lower than a voltage applied between the first node 1 and the second node 2, preferably at most (100/n+20)% of the voltage applied between the first node 1 and the second node 2, more preferably at most (100/n+10)% of the voltage applied between the first node 1 and the second node 2;
a maximum voltage drop between the gate G and the source S of each transistor 210, 220 is limited to a value which is lower than a voltage applied between the first node 1 and the second node 2, preferably at most (100/n+20)% of the voltage applied between the first node 1 and the second node 2, more preferably at most (100/n+10)% of the voltage applied between the first node 1 and the second node 2; preferably, a maximum voltage drop between the gate G and the source S of each transistor 210, 220 is limited to a value which is lower than a threshold voltage of the transistor; and
a maximum voltage drop between the drain D and the gate G of each transistor 210, 220 is limited to a value which is lower than a voltage applied between the first node 1 and the second node 2, preferably at most (100/n+20)% of the voltage applied between the first node 1 and the second node 2, more preferably at most (100/n+10)% of the voltage applied between the first node 1 and the second node 2.

Note that the voltage between the drain D and the bulk B does not have to be limited.

The second branch 200 is connected to the first branch 100 in a branch connection node which is different from the first node 1 and the second node 2. The branch connection node is electrically connected to the interconnection node 215 of the second branch 200 and to a triggering node 121 of the triggering device 120 of the first branch 100. Here the triggering node 121 is the same node as the one used to trigger the switching device 110, but the triggering node may also be any internal node 122 of the triggering device 120, e.g. an internal node between two diodes of the triggering device 120, see further.

Preferably, the switching device 110 comprises or consists of a silicon controlled rectifier, SCR. In the illustrated example, the SCR 110 comprises a first NPN bipolar transistor 111, a second PNP bipolar transistor 112 and a resistor 113. The triggering device 120 is connected between a trigger tap G2 of the second bipolar transistor 112 of the SCR 110 and the second node 2.

Preferably, the ESD protection device further comprises a transient detector 300 coupled between the first node 1 and the second node 2. The transient detector 300 comprises a resistive element 310 and a capacitive element 320, wherein the gate G of the first transistor 210 is connected to an intermediate node 315 between the resistive element 310 and the capacitive element 320.

Preferably, the triggering device 120 comprises at least one diode, more preferably at least a first diode 125 and a second diode 126 connected in series between the second node 2 and a trigger tap G2 of the switching device 110. Here the trigger tap G2 and thus also an output trigger node 121 of the triggering device 120 is connected to the interconnection node 215.

Preferably the holding device 130 comprises at least one diode, more preferably at least a first diode 135 and a second diode 136 connected in series, here between the first node 1 and the switching device 110. Optionally, a resistive element 240 may be coupled between the interconnection node 215 and the gate G of the second transistor 220.

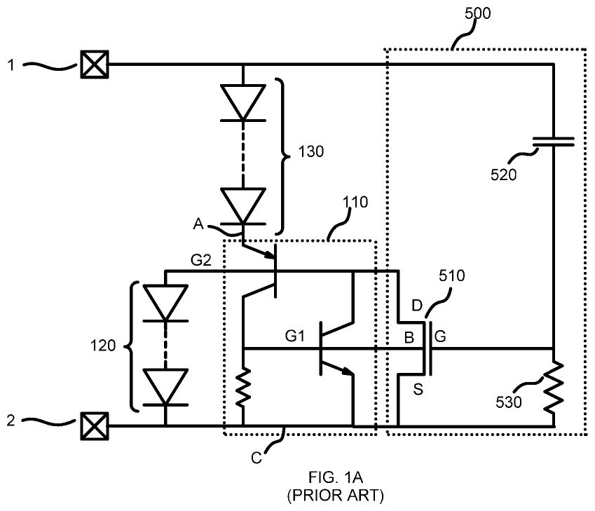

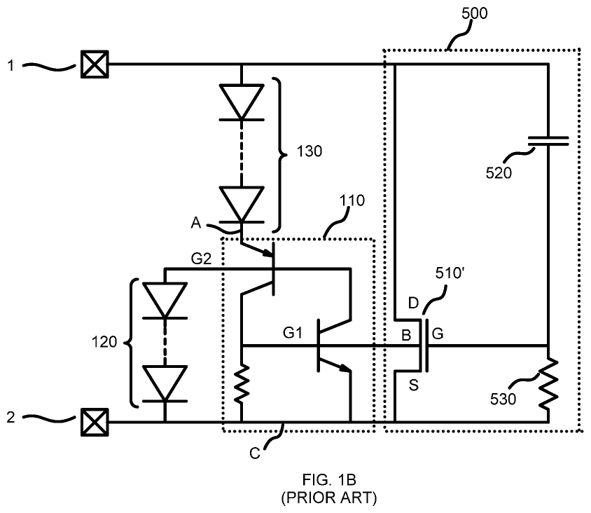

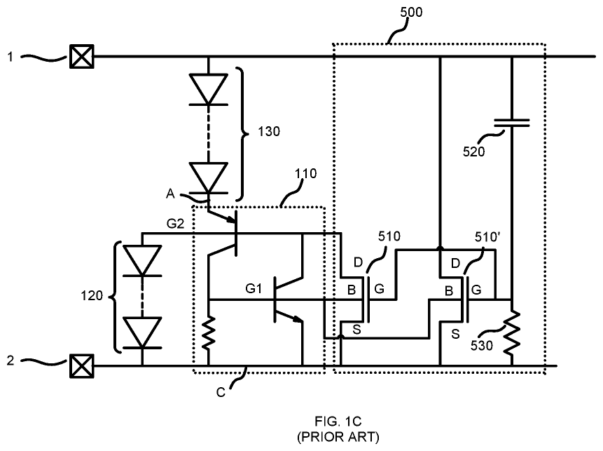

Thus, in FIG. 2, the middle interconnection node 215 of the stacked MOS transistors is coupled to the trigger tap G2. The stack of the diodes in the first branch 100, i.e. the holding diodes 135, 136 and the A/G2 diode (base-emitter junction) of the second bipolar transistor 112 of the SCR 110, will control the voltage on the middle interconnection node 215. An additional advantage is that the middle interconnection node 215 is now coupled to the trigger tap G2 of the SCR 110. Instead of using a transient triggering circuit with a first transistor 510 coupled to trigger tap G2 and a second transistor 510′ (coupled to the first node 1) to limit the overshoot, as in FIG. 1C, both functions are now included in the same stack comprising transistors 210, 220 instead of using two separate stacks 510, 510′. Moreover, the voltage rating of transistors 210, 220 can be reduced compared to the voltage rating of transistors 510, 510′, as the transistors 210, 220 do not have to stand the full voltage applied between the first node 1 and the second node 2. Also, in the embodiment of FIG. 2, the need for an additional voltage controller, such as a stack of resistive elements, is avoided.

In advanced CMOS processes, like in fin field-effect transistors, FinFETs, the available MOS transistors have a lower voltage rating. In older technologies the highest voltage rating available is 5V or 3.3V/2.5V. However, for these advanced technologies the transistors with the highest available voltage rating have a voltage rating of only 1.8V or even only 1.2V. On the other hand, the advanced technologies have the advantage of a higher speed and smaller areas for the same amount of transistors. The lower voltages inside the chip have their advantages, but the communication to the outside should also be considered. For this communication, very often, specific protocols (like USB, HDMI, . . . ) are used to be compatible with other products. For example, for USB 3.3V/5V is used. By using a second branch 200 with stacked transistors it becomes possible to withstand the higher voltages using MOS transistors made according to these advanced technologies. Preferably, the maximum voltage over each transistor should be kept below the maximum voltage rating.

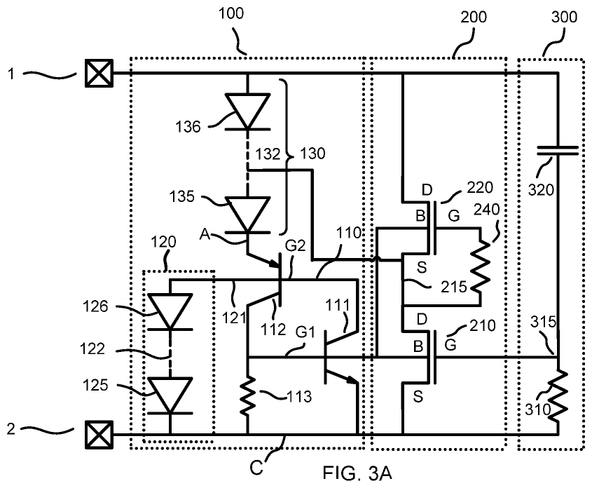

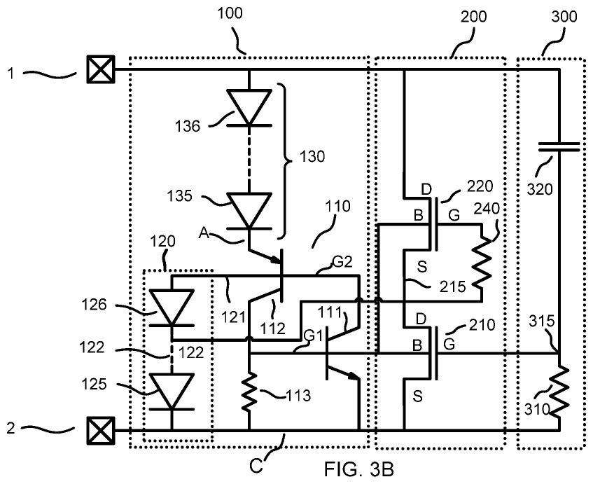

FIG. 3A illustrates a first variant of the embodiment of FIG. 2. In this embodiment, instead of connecting the trigger tap G2 to the interconnection node 215, an internal node 132 of the holding device 130 is connected to the interconnection node 215. More in particular, the holding device 130 comprises at least a first diode 135 connected in series with a second diode 136, and a diode interconnecting node 132 interconnecting the diodes 135, 136 is connected to the interconnection node 215. Instead of connecting an internal node 132 of the holding device 130 to the interconnection node 215, also the node 131, i.e. the anode A of the SCR 110, could be connected to the interconnection node 215 (not shown).

FIG. 3B illustrates a second variant of the embodiment of FIG. 2. In this embodiment, instead of connecting trigger node 121 to the interconnection node 215, an internal trigger node 122 of the triggering device 120 is connected to the interconnection node 215. More in particular, the triggering device 120 comprises a first diode 125 and a second diode 126. The internal trigger node 122 is a diode interconnecting node interconnecting diodes 125, 126 and this node 122 is connected to the interconnection node 215.

When comparing the embodiments of FIGS. 2 and 3B with the embodiment FIG. 3A, the former two embodiments have the advantage that current is pulled out of the trigger input G2 through the base-emitter junction of bipolar transistor 112 of the SCR 110 by the second branch 200, which helps in turning on the SCR 110.

In the embodiments of FIG. 2 and FIGS. 3A and 3B, the lower MOS transistor 210 has an RC trigger formed by transient detector 300 and for the upper MOS transistor 220 only a resistor 240 is added. This is one of the preferred implementations, but an additional capacitor (not shown) could be added between the drain D and the gate G of the upper second MOS transistor 220.

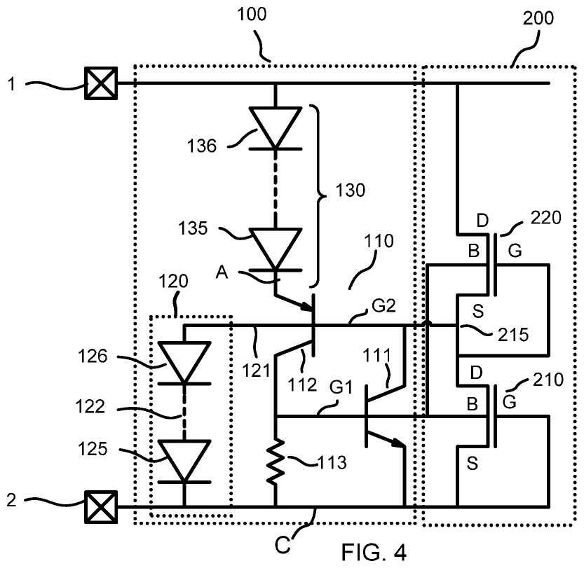

Also, other connections or gate couplings of the transistors 210, 220 are possible. Another exemplary implementation is shown in FIG. 4 where the gate G of each MOS transistor 210, 220 is coupled to the source S thereof.

In the embodiments of FIGS. 2, 3A, 3B and 4, the bulk B of each transistor 210, 220 is coupled to the bulk G1 of the SCR 110, or alternative directly to the substrate or to ground. Note that resistive element 113 could also be a substrate resistor. This may be for example the case when all the transistors 210, 220, 111 are positioned in the substrate. Alternatively, the bulk G1 of the SCR 110 could be floating, but this is generally not preferred because of leakage risks. Also, the bulk B of each of the transistors 210, 220 could be coupled to the source S of the respective transistor 210, 220 if an isolation such as a deep N-well is present.

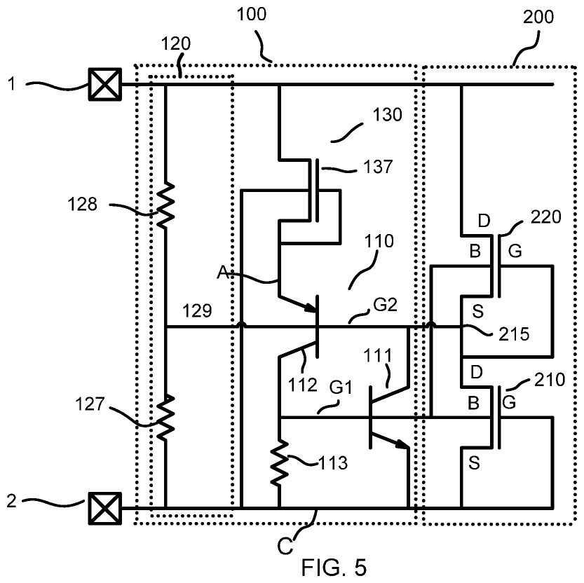

Further, the way the maximum voltage over each transistor 210, 220 is controlled may be changed. In the embodiment of FIG. 5, the triggering device 120 comprises a resistive divider with a first resistive element 127 and a second resistive element 128 coupled between the first node 1 and the second node 2. An intermediate node 129 of the resistive divider is coupled to the trigger tap G2 of the switching device 110 and to the interconnection node 215. The resistive elements 127, 128 could be resistors such as metal/poly resistors, but could also be one or more MOS devices (not shown) used in a stack.

Also, instead of one or more diodes, a different type of one or more holding elements may be used in the holding device 130. A possible implementation is shown in FIG. 5. In this example, the holding diodes are replaced by at least one MOS transistor 137.

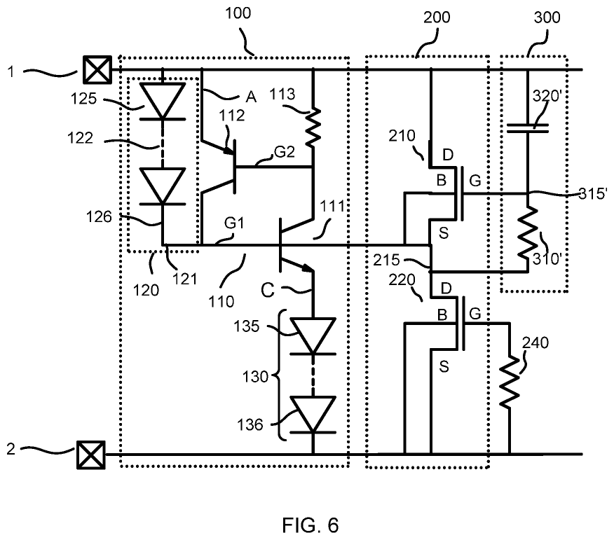

FIG. 6 illustrates an embodiment which is similar to the embodiment of FIG. 2 but where the holding device 130 is located between the second node 2 and the SCR 110, and the SCR 110 is directly connected to the first node 1. Here, the transient detector 300 is coupled between the first node 1 and the interconnection node 215. The transient detector 300 comprises a resistive element 310′ and a capacitive element 320′, and the gate G of the first transistor 210 is connected to an intermediate node 315′ between the resistive element 310′ and the capacitive element 320′. Optionally, a resistive element 240′ may be coupled between the gate G of the second transistor 220 and the second node.

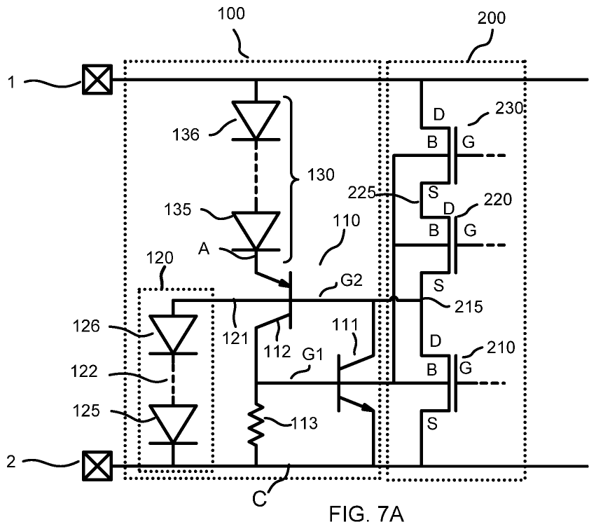

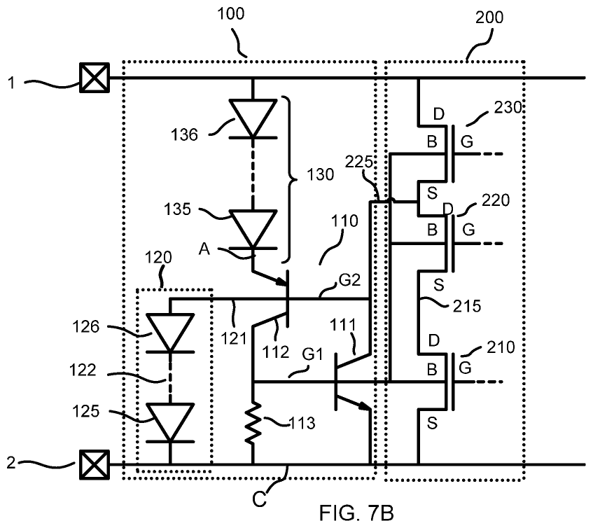

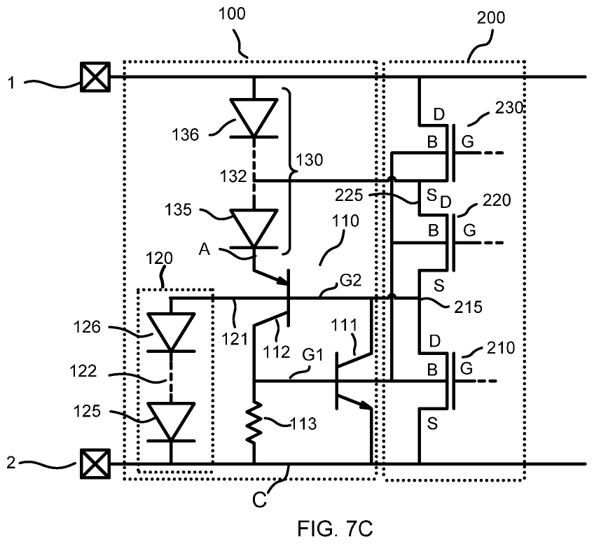

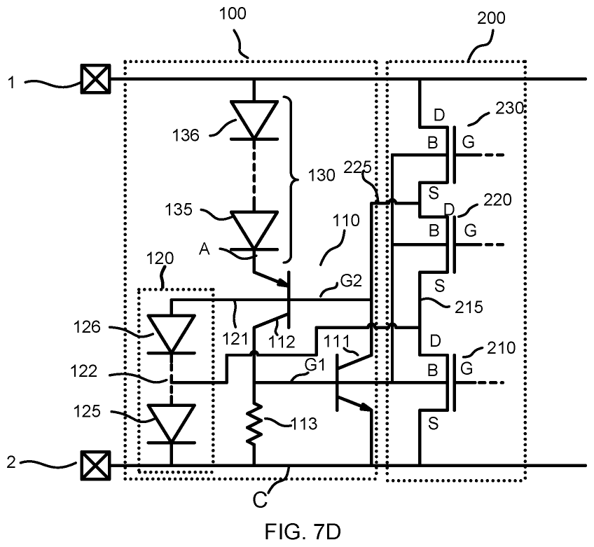

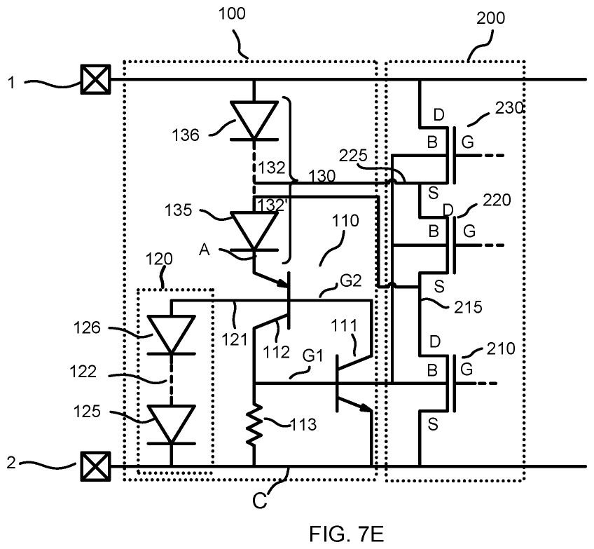

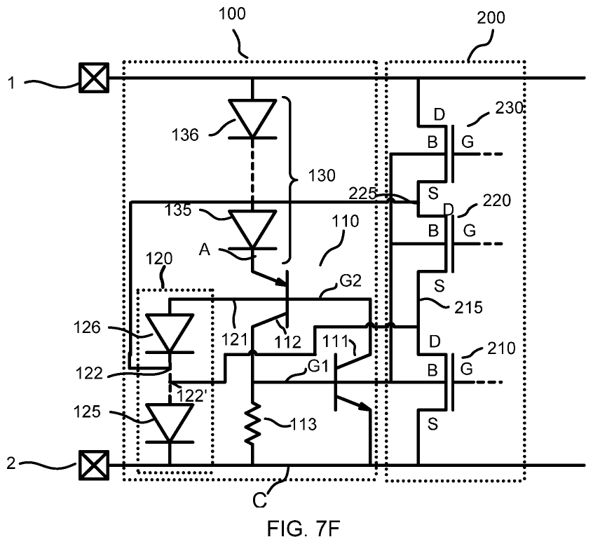

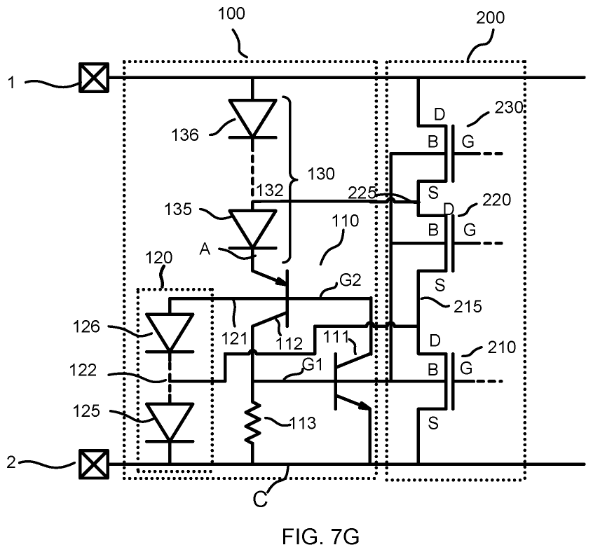

In some embodiments, a required voltage rating may be larger than two times the maximal voltage rating of a single transistor, and more than two transistors may be stacked. FIGS. 7A-7G show some exemplary implementations with a stack of three NMOS transistors 210, 220, 230 included in the second branch 200. It is noted that embodiments of the invention are not limited to a stack of two or three transistors, and the skilled person understands that similar principles apply to any number of transistors in a stack as long as the breakdown voltage is not achieved. Indeed, it should be avoided that the upper transistor of the stack can go into breakdown to the substrate. For example, typically the breakdown voltage of non-isolated NMOS transistors with a voltage rating of 1.8V is between 8V and 9V. In practice the number of transistors n that can be put in the stack is typically limited to a maximum value n_max of 3 to 5 (n_max=3-5).

FIG. 7A shows an embodiment where an interconnection node 215 between the lower NMOS transistor 210 and the middle NMOS transistor 220 is coupled to the trigger tap G2 of the SCR 110. Alternatively, as shown in FIG. 7B, the node 225 between the upper NMOS transistor 230 and the middle NMOS transistor 220 could be coupled to the trigger tap G2 of the SCR 110. One or the other option may be chosen e.g. based on the number of holding elements, such as holding diodes, of the holding device 130 and/or the number of trigger elements, such as trigger diodes, of the triggering device 120, which defines the DC voltage on the trigger tap G2.

In another further exemplary embodiment both nodes 215, 225 could be controlled, as shown in FIGS. 7C and 7D. In FIG. 7C, the upper interconnection node 225 is coupled to an internal node 132 of the holding device 130, preferably a node interconnecting two holding diodes 135, 136 of the holding device 130, and the lower interconnection node 215 is coupled to the trigger tap G2. In FIG. 7D, the upper interconnection node 225 is coupled to the trigger tap G2, and the lower interconnection node 215 is coupled to an internal node 122 of the triggering device 120, preferably a node 122 interconnecting two trigger diodes 125, 126.

Note that alternative connections are also possible. For example, both interconnection nodes 215, 225 may be each coupled to an internal node 122 of the triggering device 120 or to an internal node 132 of the holding device 130. Possible exemplary implementations are shown in FIGS. 7E-7G. In FIG. 7E, the interconnection nodes 215, 225 are connected to respective internal nodes 132, 132′ of the holding device 130 (in this embodiment at least three holding diodes may be present). In FIG. 7F, the interconnection nodes 215, 225 are connected to respective internal nodes 122, 122′ of the triggering device 120 (in this embodiment at least three triggering diodes may be present). In FIG. 7G, the interconnection node 225 is connected to an internal node 132 of the holding device 130 and interconnection node 215 is connected to internal node 122 of the triggering device 120. In general, an interconnection node which is lower in the transistor stack of the second branch 200 is coupled to a node of the first branch 100 which is lower.

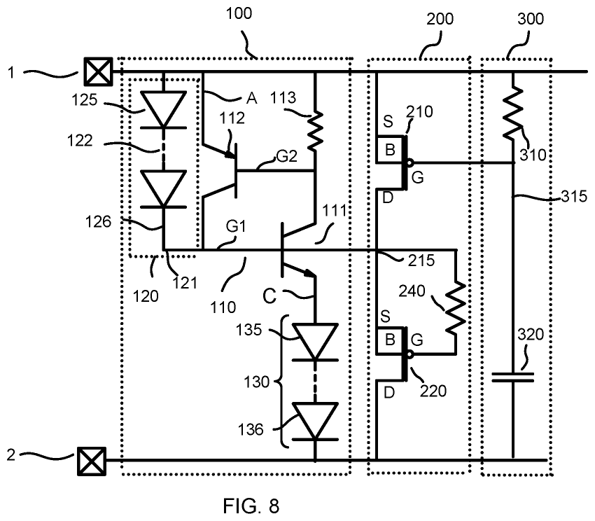

Although the previous figures show embodiments with a stack of NMOS transistors, the skilled person understands that PMOS transistors or a combination of NMOS and PMOS transistors may be used in a similar manner. An exemplary embodiment is shown in FIG. 8. One or both bulks B of PMOS transistors 210, 220 could also be coupled to the trigger tap G1 of the SCR 110. The triggering device 120 is here connected between a trigger tap G1 of the SCR and the first node 1.

Instead of MOS transistors, the device could also contain other devices like bipolar transistors, diodes, capacitors, etc.

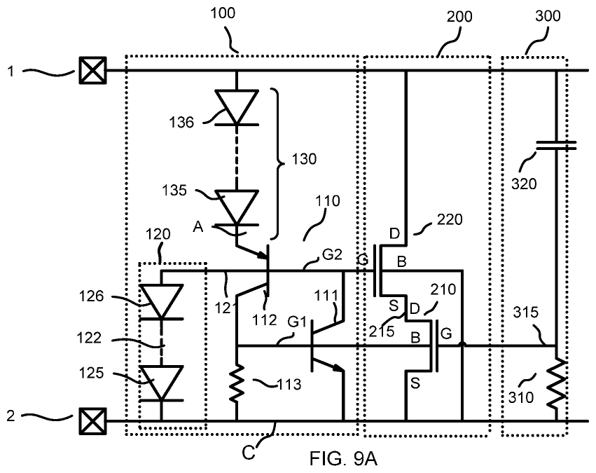

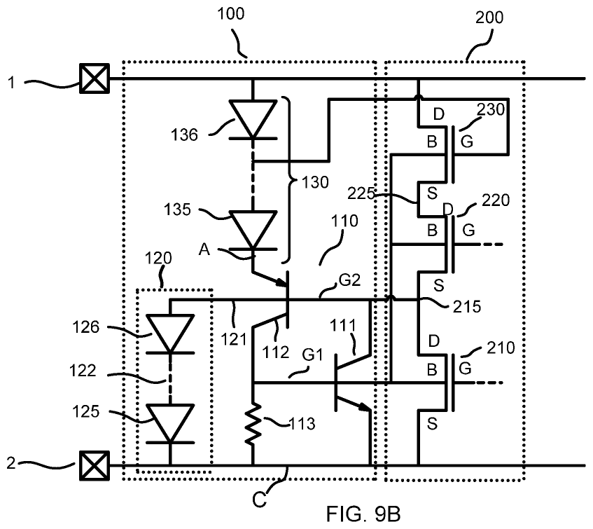

In the embodiments of the figures discussed above the voltage between the drain D and source S of each transistor of the stack of transistors is controlled by connecting the interconnection node to the first branch 100, but also other nodes of the stack of transistors could be controlled. FIG. 9A and 9B show exemplary embodiments where the voltage on the gate G of one of the transistors of the stack is controlled. For example, in FIG. 9A, a two transistor stack implementation is used, and the gate G of the upper transistor 220 is coupled to the trigger tap G2 of the SCR 110. Alternatively, the gate G of the upper transistor 220 could be connected to an internal node 122, 132 of the triggering device 120 or of the holding device 130 or to the anode A of the SCR 110. This upper transistor 220 will act as a source follower, so also limiting the voltage on the drain D of the lower transistor 210. FIG. 9B shows an exemplary embodiment where a stack with three transistors 210, 220, 230 is used. A combination of controlling the drain D of the lower transistor 210 via the trigger tap G2 and controlling the gate G of the upper MOS transistor 230 via a node 132 of the holding device 130 is implemented.

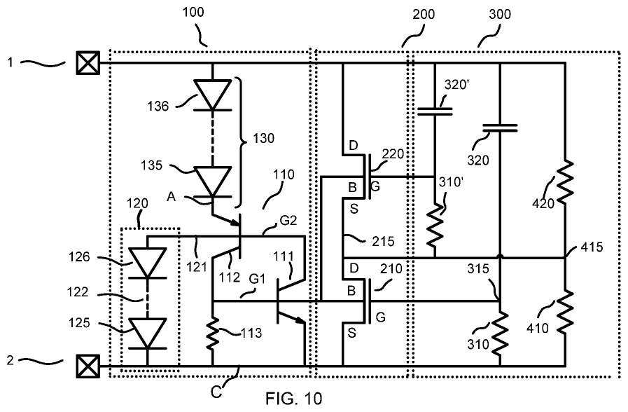

FIG. 10 illustrates a further exemplary embodiment of an ESD protection device comprising a first branch 100, and a second branch 200 and a resistive divider 400 coupled between the first node 1 and the second node. The first branch 100 and the second branch 200 are similar to the first and second branch 200 of FIG. 2, with this difference that resistor 240 has been replaced by transient detector 310′, 320′. The resistive divider 400 comprises a first resistive element 410 and a second resistive element 420. An intermediate node 415 interconnecting the first resistive element 410 and the second resistive element 420 of the resistive divider is coupled to the interconnection node 215 of the second branch 200. Thus, each MOS transistor 210, 220 has his own RC trigger circuit 310, 320; 310′, 320′ and a voltage divider 400 is added to control the voltage on the interconnection node 215 of the stack.

In the context of the present disclosure, a resistive element may be any element over which a voltage is created when current flows through it: it can be implemented by any device that has a resistivity characteristic, such as a resistor, diode, transistor, etc. In some embodiments transistors may be used if a different resistance value is preferred during normal operation as opposed to during ESD, or if the high temperature behavior of the transistor is superior to that of the resistor.

The voltage rating of the transistors used in the embodiments depicted in FIGS. 2-10 may be less than that of transistors of conventional ESD protection devices whilst at the same time improving the triggering possibilities.

Whilst the principles of the invention have been set out above in connection with specific embodiments, it is to be understood that this description is merely made by way of example and not as a limitation of the scope of protection which is determined by the appended claims.

1. An electrostatic discharge (ESD) protection device coupled between a first node and a second node, the ESD protection device comprising:
a first branch between the first node and the second node, the first branch comprising a switching device and a triggering device coupled to the switching device, the triggering device configured to switch on the switching device during an ESD event;
a second branch between the first node and the second node, the second branch comprising a stack of transistors, wherein an interconnection node interconnects a first transistor and a second transistor of the stack, wherein the second branch is electrically connected such that, in operation, a direct current (DC) voltage drop between the interconnection node and the first node is lower than a DC voltage applied between the second node and the first node.

2. The ESD protection device of claim 1, wherein the stack of the transistors is a stack of n transistors, and wherein the stack is electrically connected such that, in operation, at most (100/n+20)% of the DC voltage is applied between the second and the first node.

3. The ESD protection device of claim 1, wherein the second branch is connected to the first branch via a branch connection node which is different from the first and the second node.

4. The ESD protection device of claim 3, wherein the branch node connects the interconnection node to either a gate or a base of a transistor in the stack of transistors of the second branch.

5. The ESD protection device of claim 3, wherein the branch connection node is electrically connected to a triggering node of the triggering device of the first branch.

6. The ESD protection device of claims 1, wherein the first branch comprises a holding device connected in series with the switching device between the first and the second node, wherein the holding device comprises at least one diode.

7. The ESD protection device of claims 3, wherein the first branch comprises a holding device connected in series with the switching device between the first and the second node, wherein the holding device comprises at least one diode, and wherein the branch connection node is electrically connected to an internal node of the holding device or to an anode of the switching device.

8. The ESD protection device of claim 1, wherein the stack of transistors is a stack of at least two metal oxide semiconductor (MOS) transistors.

9. The ESD protection device of claim 1, wherein each of the transistors of the stack has a voltage rating below 2.0V.

10. The ESD protection device of claim 1, wherein the switching device comprises a silicon controlled rectifier, (SCR), wherein the triggering device is connected between a trigger tap of the SCR and one of the second node and the first node.

11. (canceled)

12. The ESD protection device of claim 1, further comprising a transient detector, coupled between the first node and the second node or between the first node and the interconnection node, the transient detector comprising a resistive element and a capacitive element, wherein a gate or a base of at least one transistor of the stack is connected to an intermediate node between the resistive element and the capacitive element.

13. The ESD protection device of claim 1, further comprising a resistive element coupled between the interconnection node and a gate or a base of the first transistor or a gate or base of the second transistor.

14. The ESD protection device of claim 1, wherein a transistor of said the stack has a gate, a source and a drain, wherein the gate is connected to the source.

15. The ESD protection device of claim 1, wherein the triggering device comprises at least one diode.

16. The ESD protection device of claim 3, wherein the triggering device comprises at least two diodes connected in series and a diode interconnecting node, wherein the diode interconnecting node interconnects two diodes of the at least two diodes, and wherein the interconnecting node is connected to the branch connection node.

17. The ESD protection device of claim 1, wherein the triggering device comprises a resistive divider coupled between the first node and the second node, wherein an intermediate node of the resistive divider is coupled to a trigger tap of the switching device.

18. (canceled)

19. The ESD protection device of claim 3, wherein the first branch comprises a holding device connected in series with the switching device between the first and the second node, and wherein the holding device comprises at least two diodes connected in series, wherein a diode interconnecting node interconnects two diodes of the at least two diodes, and wherein the diode interconnecting node is connected to the branch connection node.

20. The ESD protection device of claim 1, wherein the stack comprises at least three transistors.

21. The ESD protection device of claim 1, comprising a resistive divider coupled between the first node and the second node, wherein an intermediate node of the resistive divider is coupled to the interconnection node.

22. An electrostatic discharge (ESD) protection device coupled between a first node and a second node, the ESD protection device comprising:
a first branch between the first node and the second node, the first branch comprising a switching device and a triggering device coupled to the switching device, the triggering device configured to switch on the switching device during an ESD event;
a second branch between the first node and the second node, the second branch comprising a stack of transistors, wherein an interconnection node interconnects a first transistor and a second transistor of the stack, wherein the second branch is connected to the first branch via a branch connection node that is different than the first node and the second node.

23. The ESD protection device of claim 22, wherein the branch node connects the interconnection node to either a gate or a base of a transistor in the stack of transistors of the second branch.

24. The ESD protection device of claim 22, wherein the branch connection node is electrically connected to a triggering node of the triggering device of the first branch.

25. The ESD protection device of claim 22, wherein the first branch comprises a holding device connected in series with the switching device between the first and the second node, wherein the branch connection node is electrically connected to an internal node of the holding device.

26. (canceled)
